(19) United States
(12) Patent Application Publication
(10) Pub. No.: US 2005/0130354 A1
(43) Pub. Date: Jun. 16, 2005

(54) Metal oxide semiconductor (MOS) transistor including a planarized material layer and method of fabricating the same

(76) Inventors: Jin-young Kim, Seoul (KR); Maeda Shigenobu, Seongnam-si (KR); Chang-jin Kang, Suwon-si (KR); Jeong-hwan Yang, Suwon-si (KR)

Correspondence Address: LEE & STERBA, P.C., Suite 2000, 1101 Wilson Boulevard, Arlington, VA, 22209, US

(21) Appl. No.: 10/988,584

(22) Filed: Nov. 16, 2004

(30) Foreign Application Priority Data
Dec. 13, 2003 (KR) 03-90942

(51) Int. Cl. H01L 21/84; H01L 21/00; H01L 21/336

(52) U.S. Cl. 438/151; 438/164

(57) ABSTRACT

A method of fabricating a MOS transistor, and the MOS transistor fabricated by the method, includes providing a substrate, forming a predetermined layer having a non-planar surface on the substrate, the predetermined layer including at least one active region, forming a gate electrode material layer on the non-planar, predetermined layer, forming a material layer and a hard mask layer on an entire surface of the gate electrode material layer, and planarizing a top surface of the material layer to form a planarized material layer, forming a photoresist pattern on the planarized material layer and the hard mask layer to pattern the gate electrode material layer, forming a hard mask pattern by etching the hard mask layer using the photoresist pattern as an etching mask, and forming a predetermined pattern by etching the planarized material layer and the gate electrode material layer according to a shape of the hard mask pattern.

### BACKGROUND OF THE INVENTION

1. Field of the Invention

The present invention relates to a semiconductor transistor and a method of fabricating the same. More particularly, the present invention relates to a metal oxide semiconductor (MOS) transistor including a material layer having a planarized top surface, i.e., a planarized material layer, and a method of fabricating the same.

2. Description of the Related Art

Due to the increasing integration of semiconductor devices, lengths of gate channels are decreasing. A short channel length creates various problems, such as a short channel effect, and imposes limitations on a formation of fine patterns and an operation speed. The short channel effect is an especially significant problem. For example, an increase in a field near a drain region creates a punch-through, in which a drain depletion region penetrates a potential barrier around a source region. Resultantly, thermions create an avalanche and a perpendicular field reduces carrier mobility.

Accordingly, research into various channel structures has been conducted to secure channel length. However, such a change in channel structure creates a non-planar layer having a step difference.

FIG. 1 illustrates a perspective view of an example of a conventional MOS transistor. Referring to FIG. 1, active regions 12 protrude from an integrated circuit substrate 10, for example, a silicon substrate. An insulating layer (not shown), for example, a buried oxide layer, may be formed on a top surface of the substrate 10. A gate insulating layer 14 is formed only on channel regions of the top surface and channel regions of side surfaces of the active regions 12. A gate electrode 16, which is formed from a gate electrode material layer, is disposed on the gate insulating layer 14 and the exposed substrate 10. A hard mask 18 and an anti-reflection layer 20 are consecutively stacked on the gate electrode 16. A top surface of the anti-reflection layer 20 is planarized for a photo-etching process. A predetermined layer, for example, a photoresist pattern 22, is disposed on the anti-reflection layer 20 to form a gate structure.

If the active regions 12 become non-planar due to a change in the channel structure, however, the gate electrode material layer, which is formed on the active regions 12 gains a step difference equal to a height of the active regions. To proceed with a photo-etching process, the anti-reflection layer 20 is coated to fill the step difference and form a planarized top surface. As a result, a planarized top surface is formed on the non-planar surface.

In this case, the anti-reflection layer 20 with the planarized top surface has a varying thickness depending on position. In particular, while the anti-reflection layer 20 on one of the active regions 12 is thin (a), the anti-reflection layer 20 on the substrate 10 between the active regions 12 is relatively thick (b).

To form a gate structure on the active regions 12, a hard mask defining the gate structure is required. Excessive time, however, is spent etching the anti-reflection layer 20 at a location on the substrate 10 having the thickness (b). Such over-etching damages the photoresist pattern 22 and leads to a poor hard mask profile. In some cases, notching or breaking occurs in the pattern, thereby leading to the distortion of the hard mask 18. Furthermore, over-etching excessively recesses the gate electrodes 16 located on the active regions 12 and thus, damages the active regions 12.

### SUMMARY OF THE INVENTION

The present invention is therefore directed to a metal oxide semiconductor (MOS) transistor including a planarized material layer having a planarized top surface and a method of fabricating the same, which substantially overcome one or more of the problems due to the limitations and disadvantages of the related art.

It is a feature of an embodiment of the present invention to provide a method of fabricating a metal oxide semiconductor (MOS) transistor that is capable of preventing over-etching during formation of a hard mask used to etch a non-planar gate electrode material layer.

It is another feature of an embodiment of the present invention to provide a MOS transistor fabricating using the method.

At least one of the above and other features and advantages of the present invention may be realized by providing a method of fabricating a metal oxide semiconductor (MOS) transistor including a planarized material layer, the method including providing a substrate, forming a predetermined layer having a non-planar surface on the substrate, the predetermined layer including at least one active region, forming a gate electrode material layer on the non-planar, predetermined layer, forming a material layer and a hard mask layer on an entire surface of the gate electrode material layer, and planarizing a top surface of the material layer to form a planarized material layer, forming a photoresist pattern on the planarized material layer and the hard mask layer to pattern the gate electrode material layer, forming a hard mask pattern by etching the hard mask layer using the photoresist pattern as an etching mask, and forming a predetermined pattern by etching the planarized material layer and the gate electrode material layer according to a shape of the hard mask pattern.

The non-planar, predetermined layer may include the at least one active region having a silicon-on-insulator (SOI) structure, the at least one active region being located on the substrate. The non-planar, predetermined layer may include the at least one active region protruding from a silicon substrate.

The gate electrode material layer may have a step difference caused by the at least one active region. The gate electrode material layer may be a material selected from the group consisting of polysilicon, aluminum (Al), tungsten (W), tungsten nitride (WNₓ), tantalum (Ta), tantalum nitride (TaN), ruthenium (Ru), titanium (Ti), titanium nitride (TiN), platinum (Pt), and a combination of these elements.

The planarized material layer may be a spin-on-glass (SOG) layer.

The SOG layer may include one bond selected from the group consisting of Si—O, Si—N, Si—N, and N—H bonds, in a back bone thereof. The SOG layer may be baked for between about one minute to five minutes at temperatures of between about 100 to 500° C. The SOG layer may be planarized by wet blanket etching.

The method may further include forming an anti-reflection layer on the planarized material layer before forming the photoresist pattern.

The predetermined pattern may have a gate structure including the gate electrode, which is formed on a top surface of the at least one active region or on the top surface and at least on one side of the at least one active region.

At least one of the above and other features and advantages of the present invention may be realized by providing a metal oxide semiconductor (MOS) transistor including a planarized material layer, the MOS transistor including a predetermined layer having a non-planar surface, the predetermined layer including at least one active region, a gate electrode covering at least one surface of the at least one active region, and a gate structure formed on the gate electrode, the gate structure including the planarized material layer formed on a top surface of the gate structure.

The non-planar, predetermined layer may include the at least one active region having a silicon-on-insulator (SOI) structure being formed on a substrate. The non-planar, predetermined layer may include the at least one active region protruding from a silicon layer.

The planarized material layer may be a spin-on-glass (SOG) layer.

The MOS transistor may further include an anti-reflection layer on the planarized material layer.

The gate electrode may be formed either on a top surface of the at least one active region or on the top surface and at least on one side of the at least one active region.

### BRIEF DESCRIPTION OF THE FIGURES

The above and other features and advantages of the present invention will become more apparent to those of ordinary skill in the art by describing in detail exemplary embodiments thereof with reference to the attached drawings in which:

FIG. 1 illustrates a perspective view of a conventional metal oxide semiconductor (MOS) transistor according to the prior art; and

FIGS. 2 through 6 illustrate cross-sectional views showing stages in a method of fabricating a MOS transistor including a planarized material layer and the resultant MOS transistor according to an embodiment of the present invention.

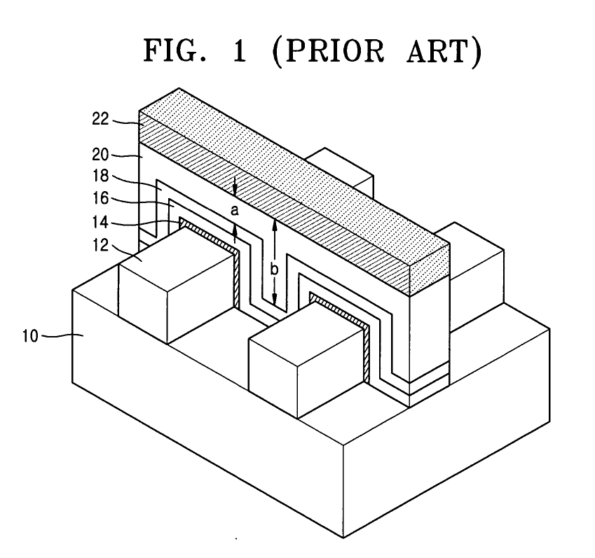

### DETAILED DESCRIPTION OF THE INVENTION

Korean Patent Application No. 2003-90942, filed on Dec. 13, 2003, in the Korean Intellectual Property Office, and entitled: “MOS Transistor Using Planarized Material Layer and Method of Fabricating the Same,” is incorporated by reference herein in its entirety.

The present invention will now be described more fully hereinafter with reference to the accompanying drawings, in which exemplary embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the figures, the dimensions of layers and regions are exaggerated for clarity of illustration. It will also be understood that when a layer is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

In an embodiment of the present invention, a planarized material layer is used to form a satisfactory hard mask profile. The planarized material layer may be a spin-on-glass (SOG) layer and, in the context of the present invention, the terms may be used interchangeably.

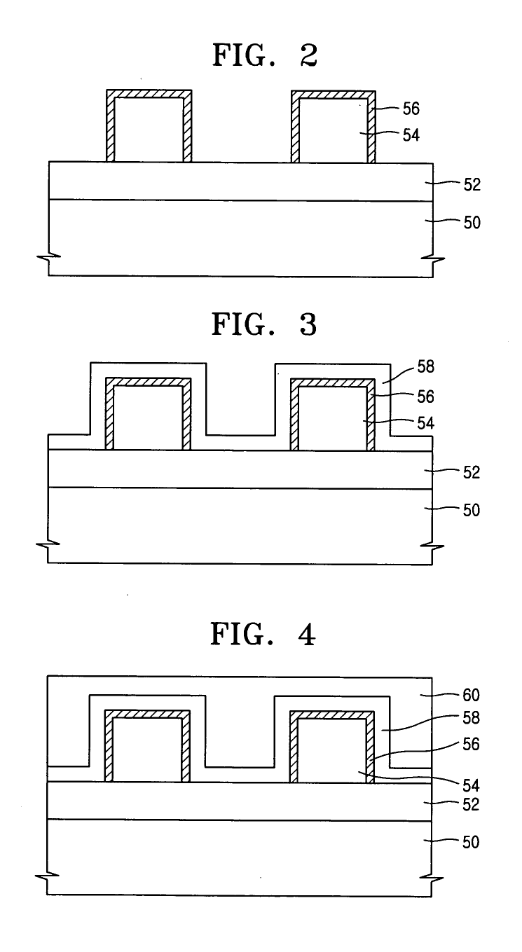

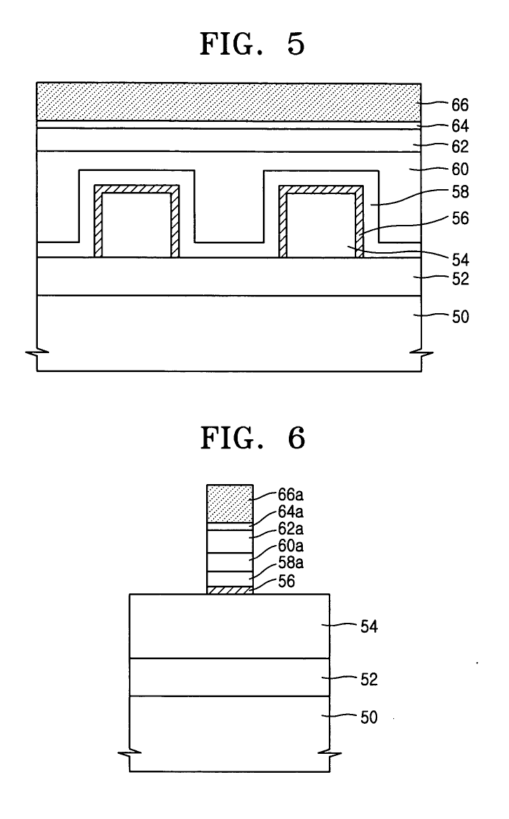

FIGS. 2 through 6 illustrate cross-sectional views showing each stage in a method of fabricating a metal oxide semiconductor (MOS) transistor including a planarized material layer. FIGS. 2 through 5 illustrate cross-sectional views in a width direction of the active region before a gate structure is formed. FIG. 6 illustrates a cross-sectional view in a length direction of the active region after a gate structure is formed. The following exemplary description will describe a MOS transistor having an active region formed on a silicon-on-insulator (SOI) substrate.

Referring to FIG. 2, a predetermined layer is formed on a substrate 50, e.g., a silicon substrate. The predetermined layer includes at least one active region 54, which may be formed protruding from a buried oxide layer 52 covering the silicon substrate 50. The active regions 54 can be arranged parallel to one another at a predetermined interval. Alternatively, the active regions 54 may be formed protruding from the silicon substrate 50. A channel region (not shown) having a predetermined width is then formed on the top surface and at least one of the side surfaces of the active regions 54. Next, a gate insulating layer 56 is formed on the channel region using a photo etching process. As a result, an upper surface of the entire substrate 50, which includes the active regions 54, becomes uneven, i.e., non-planar.

As shown in FIG. 3, a gate electrode material layer 58 covers the entire substrate 50 on which the above structure is formed. The gate electrode material layer 58 may be made of polysilicon or metals, such as aluminum (Al), tungsten (W), tungsten nitride (WNₓ), tantalum (Ta), tantalum nitride (TaN), ruthenium (Ru), titanium (Ti), titanium nitride (TiN), platinum (Pt), and compounds of these metals. The gate electrode material layer 58 has a predetermined thickness and a uniform width. For example, a polysilicon layer doped with N-type impurities, such as phosphorous (P), may be deposited using low-pressure chemical vapor deposition (LPCVD) to a thickness of about 500-4000 Å. Therefore, the upper surface of the substrate 50, on which the gate electrode material layer is formed, has an uneven surface. In other words, the active regions 54 cause a step difference in the gate electrode material layer 58.

Referring to FIG. 4, a planarized material layer 60 covers the gate electrode material layer 58. As described above, a spin-on-glass (SOG) layer may be used as the planarized material layer 60 in the present invention. Formation of the planarized material layer 60 will now be described.

Initially, an SOG solvent that forms an SOG layer 60 is coated on the gate electrode material layer 58. An SOG material for the SOG layer 60 may be a compound containing, e.g., Si—O, Si—N, Si—N, and N—H in the back bone of the compound. Examples of the SOG material include silicon oxide (SiO₂), polysiloxenes, and polysilazanes. The SOG material is dissolved in an organic solvent to obtain the SOG solvent. The solvent that may be used in the present invention is not limited to the above. For example, organic solvents or other solvents may be used. Aromatic solvents, such as xylene or ether solvents, e.g., dibutyl ether, are preferred.

In forming the planarized material layer 60, the SOG solution is coated on the gate electrode material layer 58 and hardened. The hardening process may include a pre-baking process and a main baking process.

If the pre-baking process is performed at a temperature of less than about 100° C., which is undesirable, the organic solvent can not be completely removed. If the main baking process is performed at a temperature greater than about 500° C., cracks occur due to the rapid conversion of the surface to silicon oxide. In addition, if the pre-baking process is performed for less than one minute, a portion of the organic solvent may remain. Further, if it is performed for longer than five minutes, the surface partially changes into silicon oxide and partial cracks occur. Accordingly, it is preferable that the pre-baking process be performed for between about one to five minutes at temperatures of between about 100 to 500° C.

A purpose of the main baking process is to form a silicon oxide layer. For example, a polysilazane-based SOG material has Si—N bonds in its back bone. When baked in an environment that includes oxygen and water, the Si—N bonds are substituted by Si—O bonds. When the temperature of the main baking process, by which the polysilazane is converted into a silicon oxide material, is less than about 400° C., insufficient hardening occurs so that Si—N bonds remain, thereby adversely affecting the quality of the oxide layer. When the temperature of the main baking process is greater than about 1200° C., the flatness of the silicon oxide layer may deteriorate or cracks may occur. Therefore, when a polysilazane based material is used, the main baking process is performed between temperatures of about 400 to 1200° C.

Depending on which SOG material is used, the main baking process may be omitted. For example, if the SOG material is a silicon oxide, a silicon oxide layer can be obtained by an adequate pre-baking process without performing the main baking process.

After the hardening process, the SOG layer 60 goes through a planarization process. The planarization may be performed by various methods, e.g., dry etch back, wet etch back, and chemical mechanical polishing (CMP). When considering the stability of the planarized material layer 60, wet blanket etching, for example, a wet etch back method is preferred. When needed, a hard mask layer 62 can be formed on the gate electrode material layer 58 before the SOG layer 60 is formed. Since it is easy to etch the SOG layer 60, over-etching due to the difference in thickness does not occur.

As shown in FIG. 5, a hard mask layer 62 and an anti-reflection layer 64 are consecutively formed on the planarized SOG layer 60. The hard mask layer 62 is used as an etch-stopping mask when patterning the gate electrode material layer 58. The hard mask layer 62 may be a nitride layer, an oxide layer, or a combination of both, but preferably may be a silicon oxide nitride layer (SiON).

The anti-reflection layer 64 is formed as a thin film under a photoresist layer 66 to solve problems arising from irregular reflection by the underlying layer during a photo developing process. The anti-reflection layer may be divided into two types. A first type is an inorganic anti-reflection layer that does not include carbon such as Si₃N₄, TiN, and SiON. A second type is an organic anti-reflection layer composed of a carbon-containing polymer compound. Recently, organic anti-reflection layers that can effectively reduce irregular reflection, have a uniform critical dimension (CD), and have a thickness that is easy to control have been frequently used.

When using the organic anti-reflection layer 64 as an anti-reflection layer, after performing a coating with a solution for forming the organic anti-reflection layer 64, the solution is removed by a baking process so that a solid type organic anti-reflection layer 64 is formed. The organic anti-reflection layer 64 may be composed of a large molecular weight polymer and may be formed with a thickness between about 200 Å and 1000 Å. The photoresist layer 66 is then coated on the anti-reflection layer 64. The photoresist layer 66 may be formed relatively thickly, e.g., with a thickness between about 5000 Å and 10,000 Å.

Referring to FIG. 6, for selective exposure, light is selectively illuminated through a photo mask (not shown) on the photoresist layer 66. Next, a photoresist pattern 66a, which defines a predetermined pattern, is formed by removing exposed portions by a developing process. The photoresist pattern 66a is used to etch the underlying gate electrode material layer 58 into a predetermined pattern, thereby forming a gate electrode 58a.

An anti-reflection layer pattern 64a and a hard mask pattern 62a are formed using the photoresist pattern 66a, which defines the underlying predetermined pattern, as an etching mask, eliminating the anti-reflection layer 64 and hard mask layer 62. In this case, the predetermined pattern can be a gate structure including the gate electrode 58a. The gate electrode 58a may be formed on the top surface of the active region 54 or may be formed on the top surface and at least one of side of the active region. Next, the gate structure is completed by etching the planarized material layer 60, to form a planarized material layer pattern 60a, and the gate electrode material layer 58, to form the gate electrode 58a, using the hard mask pattern 62a as an etching mask.

According to an embodiment of the present invention, since the anti-reflection layer 64 is thin and uniform, the photoresist pattern 66a is not damaged when the hard mask pattern 62a is formed. Therefore, no change of a hard mask layer 62 profile caused by damage to the photoresist pattern 66a occurs. In addition, since no damage occurs to the hard mask pattern 62a, which is disposed over the active region 54, there are no incidents of damage occurring to the active region 54 caused by hard mask pattern 62a damage.

In a MOS transistor including a planarized material layer and a method of fabricating the same according to an embodiment of the present invention, a thin, uniform anti-reflection layer can be formed, thereby preventing over-etching by coating the planarized material layer on the gate electrode material layer.

As over-etching of the anti-reflection layer is prevented, damage to the photoresist pattern is prevented, thereby resulting in a satisfactory hard mask profile and preventing damage to the active regions, caused by damage in the hard mask.

Exemplary embodiments of the present invention have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

1. A method of fabricating a metal oxide semiconductor (MOS) transistor including a planarized material layer, the method comprising:
providing a substrate;
forming a predetermined layer having a non-planar surface on the substrate, the predetermined layer including at least one active region;
forming a gate electrode material layer on the non-planar, predetermined layer;
forming a material layer and a hard mask layer on an entire surface of the gate electrode material layer, and planarizing a top surface of the material layer to form a planarized material layer;
forming a photoresist pattern on the planarized material layer and the hard mask layer to pattern the gate electrode material layer;
forming a hard mask pattern by etching the hard mask layer using the photoresist pattern as an etching mask; and
forming a predetermined pattern by etching the planarized material layer and the gate electrode material layer according to a shape of the hard mask pattern.

2. The method as claimed in claim 1, wherein the non-planar, predetermined layer comprises the at least one active region having a silicon-on-insulator (SOI) structure, the at least one active region being located on the substrate.

3. The method as claimed in claim 1, wherein the non-planar, predetermined layer comprises the at least one active region protruding from a silicon substrate.

4. The method as claimed in claim 1, wherein the gate electrode material layer has a step difference caused by the at least one active region.

5. The method as claimed in claim 1, wherein the gate electrode material layer is a material selected from the group consisting of polysilicon, aluminum (Al), tungsten (W), tungsten nitride (WNₓ), tantalum (Ta), tantalum nitride (TaN), ruthenium (Ru), titanium (Ti), titanium nitride (TiN), platinum (Pt), and a combination of these elements.

6. The method as claimed in claim 1, wherein the planarized material layer is a spin-on-glass (SOG) layer.

7. The method as claimed in claim 6, wherein the SOG layer comprises one bond selected from the group consisting of Si—O, Si—N, Si—N, and N—H bonds, in a back bone thereof.

8. The method as claimed in claim 6, wherein the SOG layer is baked for between about one minute to five minutes at temperatures of between about 100 to 500° C.

9. The method as claimed in claim 6, wherein the SOG layer is planarized by wet blanket etching.

10. The method as claimed in claim 1, further comprising forming an anti-reflection layer on the planarized material layer before forming the photoresist pattern.

11. The method as claimed in claim 10, wherein the anti-reflection layer contains an organic material.

12. The method as claimed in claim 1, wherein the predetermined pattern has a gate structure including the gate electrode, which is formed on a top surface of the at least one active region or on the top surface and at least on one side of the at least one active region.

13. A metal oxide semiconductor (MOS) transistor including a planarized material layer, the MOS transistor comprising:
a predetermined layer having a non-planar surface, the predetermined layer including at least one active region;
a gate electrode covering at least one surface of the at least one active region; and
a gate structure formed on the gate electrode, the gate structure including the planarized material layer formed on a top surface of the gate structure.

14. The MOS transistor as claimed in claim 13, wherein the non-planar, predetermined layer comprises the at least one active region having a silicon-on-insulator (SOI) structure being formed on a substrate.

15. The MOS transistor as claimed in claim 13, wherein the non-planar, predetermined layer comprises the at least one active region protruding from a silicon layer.

16. The MOS transistor as claimed in claim 13, wherein the planarized material layer is a spin-on-glass (SOG) layer.

17. The MOS transistor as claimed in claim 13, further comprising an anti-reflection layer on the planarized material layer.

18. The MOS transistor as claimed in claim 13, wherein the gate electrode is formed either on a top surface of the at least one active region or on the top surface and at least on one side of the at least one active region.
